(19) United States
(12) Patent Application Publication
(10) Pub. No.: US 2022/0201387 A1
(43) Pub. Date: Jun. 23, 2022

(54) Enclosures for Microphone Assemblies Including a Fluoropolymer Insulating Layer

(71) Applicant: Knowles Electronics, LLC, Itasca, IL (US)

(72) Inventors: Adam Ariffin, Naperville, IL (US); John Albers, Chicago, IL (US)

(21) Appl. No.: 17/599,866

(22) PCT Filed: Mar. 31, 2020
(86) PCT No.: PCT/US2020/025941

§ 371 Date: Sep. 29, 2021

Related U.S. Application Data
(60) Provisional application No. 62/827,791, filed on Apr. 1, 2019.

(51) Int. Cl. H04R 1/28; H04R 19/04; H04R 1/04; H04R 3/00; C09D 127/18; B81B 7/00; B81C 1/00

(52) U.S. Cl. CPC H04R 1/2876; H04R 19/04; H04R 1/04; H04R 3/00; C09D 127/18; B81B 7/0038; B81B 2207/012; B81C 1/00285; H04R 2201/029; H04R 2410/03; H04R 2201/003; B81B 2201/0257; B81B 7/0064

(57) ABSTRACT

A microphone assembly comprises a substrate. An acoustic transducer is disposed on the substrate, the acoustic transducer configured to generate an electrical signal responsive to acoustic activity. An integrated circuit is disposed on the substrate and electrically coupled to the acoustic transducer, the integrated circuit configured to generate an output signal indicative of the acoustic activity based on the electrical signal from the acoustic transducer. An enclosure is coupled to the substrate and defines an internal volume between the enclosure and the substrate, the enclosure having an outer surface exposed to an outside environment of the microphone assembly, and an inner surface adjacent the internal volume. An insulating layer is disposed on the inner surface of the enclosure. The insulating layer comprises a fluoropolymer.

### CROSS-REFERENCE TO RELATED APPLICATIONS

The application claims priority to and the benefit of U.S. Provisional Application No. 62/827,791, filed Apr. 1, 2019, the entire disclosure of which is incorporated herein by reference.

### TECHNICAL FIELD

The present disclosure relates generally to systems and methods for providing an insulating layer on an enclosure of a microphone assembly.

### BACKGROUND

Microphone assemblies are generally used in electronic devices to convert acoustic energy to electrical signals. Advancements in micro and nanofabrication technologies have led to the development of progressively smaller micro-electro-mechanical-system (MEMS) microphone assemblies. The small size of MEMS microphone assemblies can make them prone to noise issues. Particularly, temperature changes in the internal volume defined by the enclosure due to thermal conduction through the enclosure can contribute to noise.

### SUMMARY

Embodiments described herein relate generally to microphone assemblies that include an enclosure having a fluoropolymer insulating layer disposed on an inner surface thereof, and methods of forming the same.

In some embodiments, a microphone assembly comprises a substrate; an acoustic transducer disposed on the substrate, the acoustic transducer configured to generate an electrical signal responsive to acoustic activity; an integrated circuit disposed on the substrate and electrically coupled to the acoustic transducer, the integrated circuit configured to generate an output signal indicative of the acoustic activity based on the electrical signal from the acoustic transducer; an enclosure coupled to the substrate and defining an internal volume between the enclosure and the substrate, the enclosure having an outer surface exposed to an outside environment of the microphone assembly, and an inner surface adjacent the internal volume; and an insulating layer disposed on the inner surface of the enclosure, the insulating layer comprising a fluoropolymer.

In some embodiments, an enclosure for a microphone assembly comprises a first wall; a plurality of second walls projecting axially from the first wall, an end of each of the plurality of second walls configured to be coupled to a substrate to form an internal volume with the substrate within which components of the microphone assembly are disposed, the enclosure having an outer surface configured to exposed to an environment outside the microphone assembly, and an inner surface adjacent the internal volume; and an insulating layer disposed on the inner surface of the enclosure, the insulating layer comprising a fluoropolymer.

In some embodiments, an enclosure of a microphone assembly is formed by the process of: providing a metal sheet; depositing an insulating layer on a surface of the metal sheet, the insulating layer comprising a fluoropolymer; stamping the metal sheet to form the enclosure in the metal sheet such that the enclosure has an outer surface configured to be exposed to an environment outside the microphone assembly, and an inner surface opposite the outside surface, the insulating layer being disposed on the inner surface; and separating the enclosure from the metal sheet with the insulating layer disposed thereon.

In some embodiments, a method comprises providing a metal sheet; depositing an insulating layer on a surface of the metal sheet, the insulating layer comprising a fluoropolymer; and stamping the metal sheet to form an enclosure for a microphone assembly in the metal sheet such that the enclosure has an outer surface configured to be exposed to an environment outside the microphone assembly, and an inner surface opposite the outside surface, the insulating layer being disposed on the inner surface; and separating the enclosure from the metal sheet with the insulating layer disposed thereon.

It should be appreciated that all combinations of the foregoing concepts and additional concepts discussed in greater detail below (provided such concepts are not mutually inconsistent) are contemplated as being part of the subject matter disclosed herein. In particular, all combinations of claimed subject matter appearing at the end of this disclosure are contemplated as being part of the subject matter disclosed herein.

### BRIEF DESCRIPTION OF DRAWINGS

The foregoing and other features of the present disclosure will become more fully apparent from the following description and appended claims, taken in conjunction with the accompanying drawings. Understanding that these drawings depict only several implementations in accordance with the disclosure and are therefore, not to be considered limiting of its scope, the disclosure will be described with additional specificity and detail through use of the accompanying drawings.

FIG. 1 is a side cross-section view of a microphone assembly including an enclosure having a fluoropolymer insulating layer, according to an embodiment.

FIG. 2 shows various operations of a process for forming an enclosure of a microphone assembly having a fluoropolymer insulating layer disposed thereon, according to an embodiment.

FIG. 3 is a schematic flow diagram of a method for forming an enclosure of a microphone assembly having a fluoropolymer insulating layer disposed thereon, according to an embodiment.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION

Embodiments described herein relate generally to microphone assemblies that include an enclosure having a fluoropolymer insulating layer disposed on an inner surface thereof, and methods of forming the same.

Small MEMS microphone assemblies have allowed incorporation of such microphone assemblies in compact devices such as cell phones, laptops, wearables, TV/set-top box remotes, etc. The MEMS microphone industry faces continuous demand to reduce footprint, package volume, power consumption and cost while increasing performance and reliability. Generally, the can or enclosure which houses the components of the microphone assembly is filled with air. Miniaturization of MEMS microphone assemblies has allowed enclosures of the MEMS microphone assemblies to have very small internal volumes, for example, in a range of 1-5 mm³. The enclosure provides an electromagnetic shield as well as a protective cover for the components of the microphone assembly.

However, such MEMS microphone assemblies pose other unique challenges, particularly because of their small dimensions. For example, the enclosure may not provide sufficient electromagnetic compatibility (EMC) with RF signals that the microphone assembly may be subjected to. The RF signals, which may be produced by other components of a system in which the microphone assembly is disposed, may impinge on and be absorbed in the enclosure, causing an increase in the temperature of the enclosure. This heat is conducted into the internal volume defined by the enclosure causing an increase in the air disposed in the internal volume, which contributes to acoustic noise (e.g., due to change in density and hence partial pressure of the air present in the internal volume). In some instances, if the RF signal modulation frequency is low enough (e.g., in a range of 200-300 Hz), the enclosure temperature fluctuates at the modulation frequency. Consequently, the air within the internal volume also varies in temperature with the modulation frequency, causing pressure fluctuations that contribute to acoustic noise.

In contrast, embodiments of the microphone assemblies described herein may provide one or more benefits including, for example: (1) providing an insulation layer on an inner surface of an enclosure of the microphone assembly to reduce heat conductance into an inner volume of the enclosure, thereby reducing acoustic noise; (2) forming the insulating layer such that it is in continuous contact with a surface of the enclosure so as to provide better insulation; and (3) allowing formation of the insulating layer during the fabrication process of the enclosure, thereby reducing fabrication time, complexity, and cost.

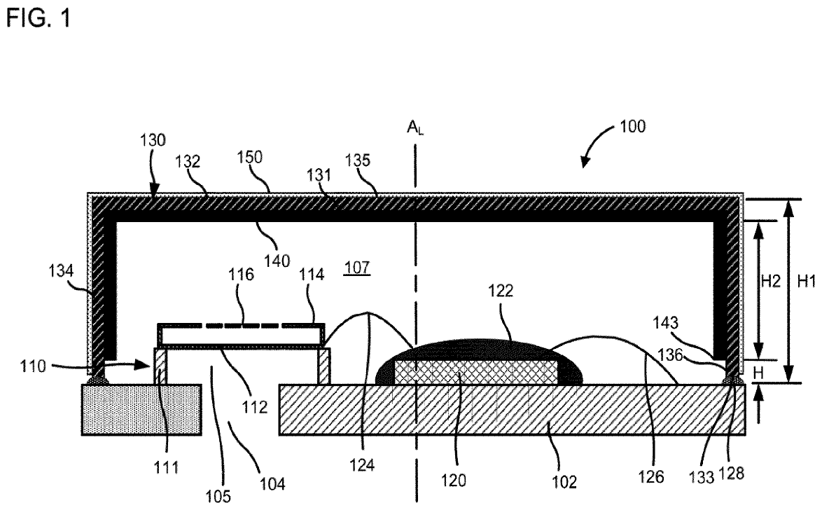

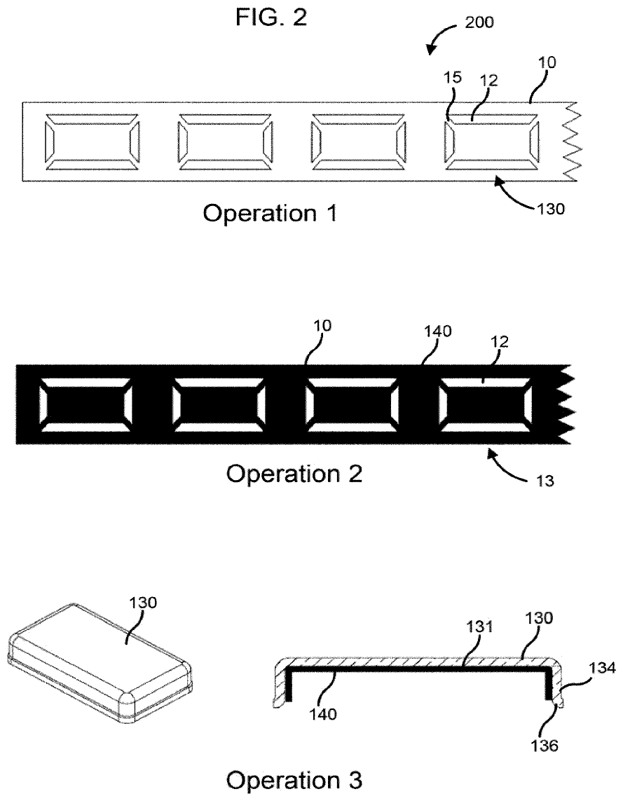

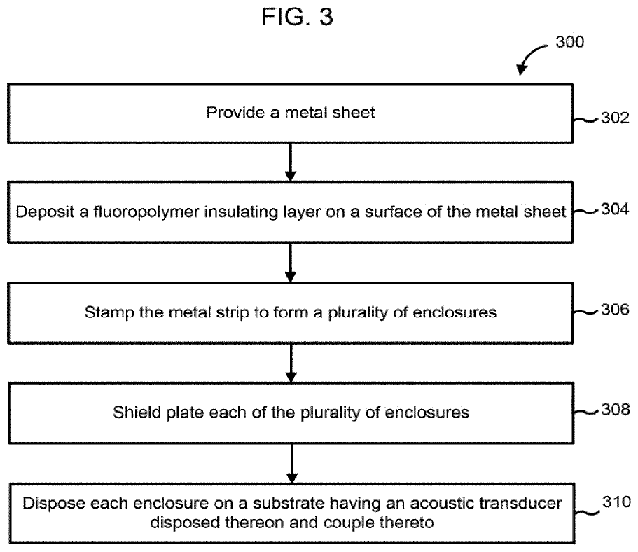

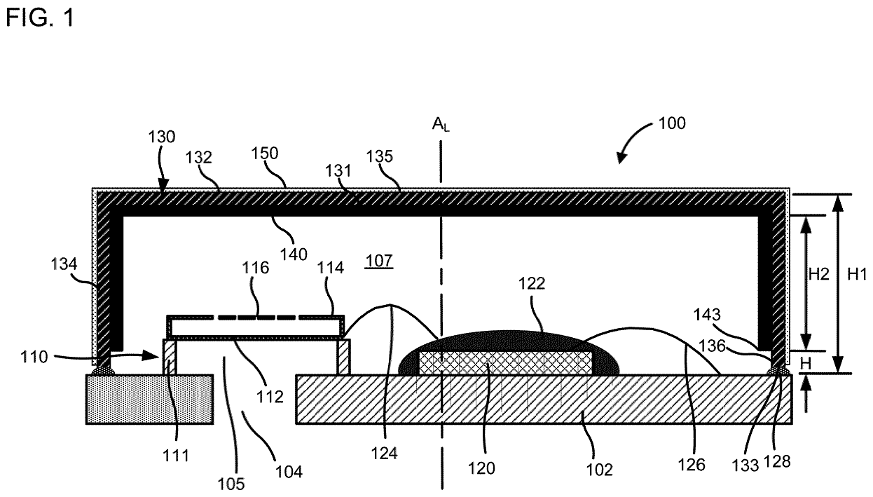

FIG. 1 is a side cross-section view of a microphone assembly 100, according to a particular embodiment. The microphone assembly 100 may be used for converting acoustic signals into electrical signals in any device such as, for example, cell phones, laptops, TV/set top box remotes, tablets, audio systems, head phones, wearables, portable speakers, car sound systems or any other device which uses a microphone assembly.

The microphone assembly 100 comprises a substrate or base 102, an acoustic transducer 110, an integrated circuit 120 and an enclosure or cover 130. The substrate 102 can be formed from materials used in printed circuit board (PCB) fabrication (e.g., plastics). For example, the substrate 102 may include a PCB configured to mount the acoustic transducer 110, the integrated circuit 120 and the enclosure 130 thereon. A sound port 104 is formed through the substrate 102. The acoustic transducer 110 is positioned on the sound port 104, and is configured to generate an electrical signal responsive to an acoustic signal received through the sound port 104.

In FIG. 1, the acoustic transducer 110 and the integrated circuit 120 are shown disposed on a surface of the substrate 102, but in other embodiments one or more of these components may be disposed on the enclosure 130 (e.g., on an inner surface of the enclosure 130) or walls of the enclosure 130 or stacked atop one another. In some embodiments, the substrate 102 includes an external-device interface having a plurality of contacts coupled to the integrated circuit 120, for example, to connection pads (e.g., bonding pads) which may be provided on the integrated circuit 120. The contacts may be embodied as pins, pads, bumps or balls among other known or future mounting structures. The functions and number of contacts on the external-device interface depend on the protocol or protocols implemented and may include power, ground, data, and clock contacts among others. The external-device interface permits integration of the microphone assembly 100 with a host device using reflow-soldering, fusion bonding, or other assembly processes.

In various embodiments, the acoustic transducer 110 may comprise a diaphragm 112, and a back plate 114 disposed above the diaphragm 112. The diaphragm 112 and the back plate 114 may be disposed on a transducer substrate 111. The diaphragm 112 may have a thickness in a range of 1-10 microns. As shown in FIG. 1, the diaphragm 112 separates a front volume 105 defined between the diaphragm 112 and the sound port 104, from the internal volume 107 that forms a back volume the microphone assembly 100 between the enclosure 130 and diaphragm 112. Thus, the microphone assembly 100 is a bottom port microphone assembly in which the sound port 104 is defined in the substrate 102 such that an internal volume 107 of the enclosure 130 defines the back volume. It should be appreciated that in other embodiments, the concepts described herein may be implemented in a top port microphone assembly in which a sound port is defined in the enclosure 130 of the microphone assembly 100.

In some implementations, the acoustic transducer 110 may include a MEMS transducer embodied as a condenser-type transducer having the diaphragm 112 movable relative to the back plate 114 in response to changes in acoustic pressure. Alternatively, the MEMS acoustic transducer 110 may include a piezoelectric device, or some other known or future electro-acoustic transduction device implemented using MEMS technology. In still other implementations, the acoustic transducer 110 is a non-MEMS device embodied, for example, as an electret or other known or future non-MEMS type transduction device.

In some embodiments, the acoustic transducer 110 may be formed from a dielectric and/or conductive material (e.g., silicon oxide, silicon nitride, silicon carbide, gold, aluminum, platinum, etc.). Movement of the diaphragm 112 in response to the acoustic signal may generate an electrical signal (e.g., a voltage corresponding to a change in capacitance thereof), which may be measured and is representative of the acoustic signal. In some implementations, vibration of the membrane relative to the back plate 114 (e.g., a fixed back plate) causes changes in the capacitance between the diaphragm 112 and the back plate 114 and corresponding changes in the generated electrical signal. In other embodiments, the acoustic transducer 110 may be formed from a piezoelectric material, for example, quartz, lead titanate, III-V and II-VI semi-conductors (e.g., gallium nitride, indium nitride, aluminum nitride, zinc oxide, etc.), graphene, ultra nanocrystalline diamond, polymers (e.g., polyvinylidene fluoride) or any other suitable piezoelectric material. In such embodiments, vibration of the acoustic transducer 110 in response to the acoustic signal may generate an electrical signal (e.g., a piezoelectric current or voltage) which is representative of the acoustic signal. In some embodiments, a pierce or throughhole is defined through the diaphragm 112 to provide pressure equalization between the front and back volumes 105 and 107. In other embodiments, a vent may be defined in the enclosure 130 to allow pressure equalization.

The back plate 114 is disposed above the diaphragm 112 such that the back plate 114 is spaced apart from the diaphragm 112. A plurality of apertures 116 are defined in the back plate 114. The back plate 114 may be formed from polysilicon, silicon nitride, other suitable materials (e.g., silicon oxide, silicon, ceramics, etc.), or sandwiches thereof. Vibrations of the diaphragm 112 relative to the back plate 114 which is substantially fixed (e.g., substantially inflexible relative to the diaphragm 112) in response to acoustic signals received on the diaphragm 112 causes changes in the capacitance between the diaphragm 112 and the back plate 114, and corresponding changes in the generated electrical signal. While the back plate 114 is disposed above the diaphragm 112 as shown in FIG. 1, in other embodiments the back plate 114 may be disposed below the diaphragm 112, or the back plate 114 may be disposed between a first and second diaphragm each of which includes the diaphragm 112 in a dual diaphragm acoustic transducer, or any other acoustic transducer.

The integrated circuit 120 is positioned on the substrate 102. The integrated circuit 120 is electrically coupled to the acoustic transducer 110, for example, via a first electrical lead 124 and also to the substrate 102 (e.g., to a trace or other electrical contact disposed on the substrate 102) via a second electrical lead 126. The integrated circuit 120 receives an electrical signal from the acoustic transducer 110 and may amplify and condition the signal before outputting a digital or analog electrical signal as is known generally. The integrated circuit 120 may also include a protocol interface (not shown), depending on the output protocol desired. The integrated circuit 120 may also be configured to permit programming or interrogation thereof as described herein. Exemplary protocols include but are not limited to PDM, PCM, SoundWire, I2C, I2S and SPI, among others.

The integrated circuit 120 may include one or more components, for example, a processor, a memory, and/or a communication interface. The processor may be implemented as one or more general-purpose processors, an application specific integrated circuit (ASIC), one or more field programmable gate arrays (FPGAs), a digital signal processor (DSP), a group of processing components, or other suitable electronic processing components. In other embodiments, the DSP may be separate from the integrated circuit 120 and in some implementations, may be stacked on the integrated circuit 120. In some embodiments, the one or more processors may be shared by multiple circuits and, may execute instructions stored, or otherwise accessed, via different areas of memory). Alternatively, or additionally, the one or more processors may be structured to perform or otherwise execute certain operations independent of one or more co-processors. In other example embodiments, two or more processors may be coupled via a bus to enable independent, parallel, pipelined, or multi-threaded instruction execution. All such variations are intended to fall within the scope of the present disclosure. For example, a circuit as described herein may include one or more transistors, logic gates (e.g., NAND, AND, NOR, OR, XOR, NOT, XNOR, etc.), resistors, multiplexers, registers, capacitors, inductors, diodes, wiring, and so on.

A protective coating 122 may be disposed on the integrated circuit 120, in some implementations. The protective coating 122 may include, for example a silicone gel, a laminate, or any other protective coating configured to protect the integrated circuit 120 from moisture and/or temperature changes.

The enclosure 130 is positioned on the substrate 102. The enclosure 130 defines the internal volume 107 within which at least the integrated circuit 120 and the acoustic transducer 110 is positioned. For example, as shown in FIG. 1, the enclosure 130 is positioned on the substrate 102 such that the substrate 102 forms a base of the microphone assembly 100, and the substrate 102 and the enclosure 130 cooperatively define the internal volume 107. As previously described herein, the internal volume 107 defines the back volume of the microphone assembly 100. The enclosure 130 may be formed from a suitable material such as, for example, metals (e.g., aluminum, copper, stainless steel, etc.), and is coupled to the substrate 102 at a bond 128. The bond 128 may include, for example, an adhesive, a solder or a fusion bond. The enclosure 130 comprises a first wall 132 and a plurality of second walls 134 projecting axially from outer edges of the first wall 132 towards the substrate 102 and contacting the substrate 102. An end 133 of the second wall 134 contacts the substrate 102 and is coupled thereto by the bond 128. The enclosure 130 includes an inner surface 131 adjacent to the internal volume 107, and an outer surface 135 exposed to an environment outside the microphone assembly 100 (e.g., ambient air).

In some instances, the microphone assembly 100 may be exposed to RF signals, for example, generated by other components of a system including the microphone assembly 100. The RF signals may absorb in the enclosure 130 and cause heating of the enclosure 130, as previously described herein. The heat is conducted into the internal volume 107 (i.e., the back volume) and heats the air contained therein, for example, corresponding to the modulation frequency of the RF signal, which contributes to acoustic noise.

To decrease thermal conduction from the enclosure 130 into the internal volume 107, an insulating layer 140 is disposed in an inner surface 131 of the enclosure 130. The insulating layer 140 comprises a fluoropolymer. The fluoropolymer may include, for example, polytetrafluoroethylene, fluorinated ethylene propylene, perfluoroalkoxy alkane, poly(ethane-co-tetrafluoroethene), polyvinylfluoride, polyvinylidene fluoride, polychlorotrifluoroethylene, fluorinated ethylene-propylene, polyethylenechlorotrifluoroethylene, chlorotrifluoroethylenevinylidene, tetrafluoroethylene-propylene, perfluoropolyether, and/or perfluorosulfonic acid. In particular embodiments, the fluoropolymer includes polytetrafluoroethylene (e.g., TEFLON®).

In some embodiments, a portion 136 of each of the plurality of second walls 134 located proximate to the substrate 102 is not covered by the insulating layer 140, i.e., the insulating layer 140 is not disposed on a portion 136 of the each of the plurality of second walls 134 proximate to the substrate 102. For example, the insulating layer 140 may be sheared off from the portion 136 during the fabrication process of the enclosure 130, as described in detail herein. Particularly, the insulating layer 140 is not disposed on the portion 136 of the each of the second walls 134 that is located between the end 133 of the corresponding second wall 134 in contact with the substrate 102, and an outer end 143 of the insulating layer 140 located proximate to the substrate 102. For example, as shown in FIG. 1, each second wall 134 has a height H1 and a portion of the insulating layer 140 disposed on the second wall 134 has height H2 selected such that the portion 136 of the second wall 134 does not have the insulating layer 140 disposed thereon. In some embodiments, the height H of the portion 136 is less than three-quarter (¾) times the height H1 of the corresponding second wall 134. For example, the portion 136 may have a height equal to or less than 100 microns. In some embodiments, the plurality of second walls 134 may be formed monolithically with the first wall 132, for example, in a stamping or molding process, as described herein.

Some conventional enclosures for use with microphone assemblies may have a pre-formed insert coupled to an inner surface of an enclosure via an adhesive. The drawbacks of such an approach include that on portions of the inner surface of such enclosures where the adhesive is not present, a gap remains between the preformed insulating layer and the corresponding surface of the enclosure, which may lead to thermal leakage into the inner volume of the enclosure, and therefore provided inferior thermal insulation. Furthermore, since enclosures for microphone assemblies have small dimensions (e.g., 1-5 mm³), accurate positioning of such preformed inserts into the enclosure is tedious and prone to errors. Complicated jigs and fixtures are needed which significantly increases manufacturing complexity and cost.

In contrast, the insulating layer 140 is in continuous contact with the corresponding inner surface 131 of the enclosure 130. For example, the insulating layer 140 may be spray coated, dip coated, drop coated, vapor deposited, or disposed using any other suitable means on the inner surface 131 of the enclosure 130 such that the insulating layer 140 is continuous contact therewith. Thus, there is no air gap between the insulating layer 140 and the inner surface 131, therefore enabling the insulating layer 140 to provide superior insulation.

In this manner, the complicated steps of alignment, positioning and adhering that are used with preformed inserts are eliminated, thereby reducing manufacturing complexity and cost. In addition, the insulating layer 140 is removed from the portion 136 of the second walls 134 during or after the fabrication of the enclosure 130. This facilitates bonding of the end 133 of the second walls 134 of the enclosure 130 to the substrate 102 via the bond 128 without the insulating layer 140 interfering with the bonding process.

In some embodiments, the insulating layer 140 has a thickness in a range of 30-120 microns, inclusive. For example, the insulating layer 140 may have a thickness in a range of 30-60 microns, 60-90 microns, or 90-120 microns, inclusive, or any other suitable thickness. In particular embodiments, the insulating layer 140 has a thickness of in a range of 30-40 microns, inclusive.

In some embodiments, a shielding layer 150 of a shielding material may be also be disposed on surface of the enclosure 130 that do not include the insulating layer 140 disposed thereon, for example, the outer surface 135. The shielding material may include copper, nickel, tin, chrome, gold, or any other suitable material, and is configured to provide additional electromagnetic shielding, for example, to improve signal-to-noise ratio.

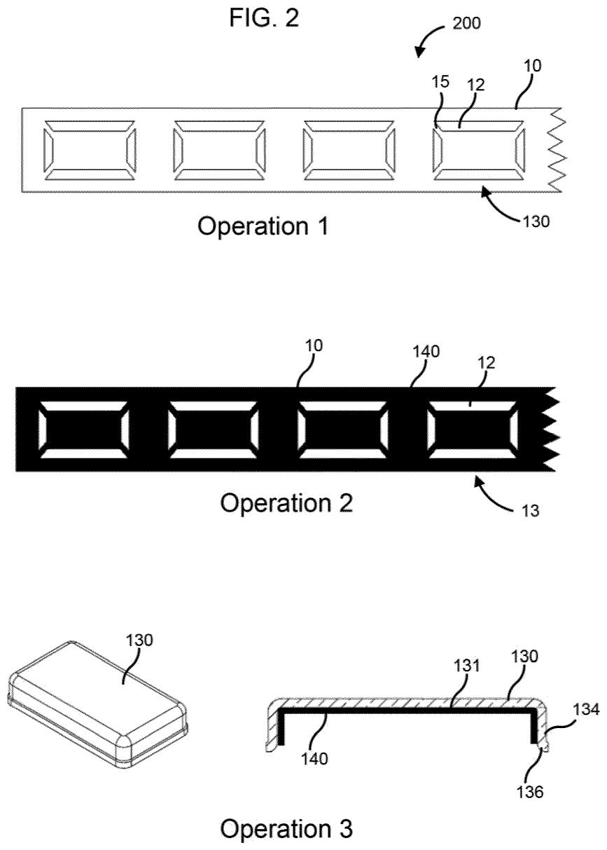

In some embodiments, the insulating layer 140 may be formed on the inner surface 131 during the fabrication process of the insulating layer 140, thereby reducing manufacturing complexity and cost. For example, FIG. 2 illustrates various operations of a process 200 for forming the enclosure 130 with the insulating layer 140 disposed thereon.

At operation 1, a metal sheet 10 is provided. The metal sheet 10 may include, for example, a strip of aluminum, stainless steel, alloys or any other suitable metal. Openings 12 may be defined in the metal sheet 10 to define outlines of a plurality of sheet portions 13, each sheet portion 13 used to form a single enclosure 130. As shown in FIG. 2, each sheet portion 13 of the metal sheet 10 from which a single enclosure 130 is formed is surrounded by the openings 12, such that each sheet portion 13 is connected to the bulk metal sheet 10 by thin anchors 15 that remain between adjacent openings 12.

At operation 2, the insulating layer 140 is deposited on a surface of the metal sheet 10 that forms the inner surface 131 of the enclosure 130. The insulating layer 140 comprises a fluoropolymer (e.g., polytetrafluoroethylene). The insulating layer 140 may be deposited on the surface of the metal sheet 10 using any suitable means. In some embodiments, the insulating layer 140 is spray coated on the surface of the metal sheet 10. In other embodiments, the insulating layer 140 may be drop coated, dip coated, or vapor deposited on surface of the metal sheet 10. The insulating layer 140 may be deposited in liquid or gaseous form, and allowed to solidify to form the insulating layer 140. In some embodiments, the metal sheet 10 may be heated to temperature (e.g., in a range of 100-200 degrees Celsius), for example, baked in an oven to cure the insulating layer 140.

At operation 3, the metal sheet 10 is stamped (e.g., using a stamping tool and a die) to form a plurality of enclosures 130 in the metal sheet 10 such that the insulating layer 140 is disposed on the inner surface 131 of the enclosure 130, and the plurality of enclosures 130 are separated from the metal sheet 10 with the insulating layer 140 disposed thereon. For example, as each sheet portion 13 is stamped to mold it into the desired shape of the enclosure 130, the stamping force is sufficient to shear the sheet portion 13 from the anchors 15 such that the enclosure 130 is separated from the metal sheet 10 during the stamping process. In other embodiments, a separate operation may be used to separate each of the plurality of enclosures 130 from the metal sheet 10.

In some embodiments, when the metal sheet 10 is stamped and the enclosures 130 are separated from the metal sheet 10, a portion of the insulating layer 140 is sheared from the portion 136 of the corresponding second wall 134 of the enclosure 130. In other embodiments, the portion of the insulating layer 140 may be removed from the portion 136 of the corresponding second wall 134 of the enclosure 130 using any suitable process, for example, an abrasive removal process, or a wet or dry chemical etch.

In some embodiments, the process 200 may also include shield plating the enclosure 130 with a shielding material. The shielding process may include an electroplating, or an electroless plating process. The shielding material may include copper, nickel, tin, chrome, gold, or any other suitable material. The fluoropolymer insulating layer 140 is able to withstand the shielding process. Thus, a plurality of enclosures 130 with the insulating layer 140 disposed thereon can be formed in a reel to reel process, the fluoropolymer insulating layer 140 capable of withstanding further post-processing operations. This allows integration of the fabrication process of the insulating layer 140 in a conventional reel to reel process for fabricating enclosures, thereby adding minimal complexity and cost to the fabrication process.

In particular embodiments, the shield plating process may include rinsing the enclosure 130 with the insulating layer 140 disposed thereon (e.g., ultrasonic rinsing in deionized water), followed by electrolytic cleaning, and acid cleaning (e.g., in sulfuric acid). A first shielding material, for example, a first metal (e.g., nickel, zinc, etc.) may be deposited on the enclosure 130 followed by electroless deposition of the first shielding material (e.g., Ni). A second shielding material, for example, a second metal (e.g., gold or platinum) may be deposited on the first metal. This is followed by one or more rinsing operation (e.g., ultrasonic rinsing in deionized water), followed by one or more drying operations (e.g., spin drying and/or oven baking). The shield plating process results in deposition of a shielding layer (e.g., the shielding layer 150) on exposed surfaces of the enclosure 130, i.e., one or more surfaces that do not have the insulating layer 140 disposed thereon (e.g., the outer surface 135).

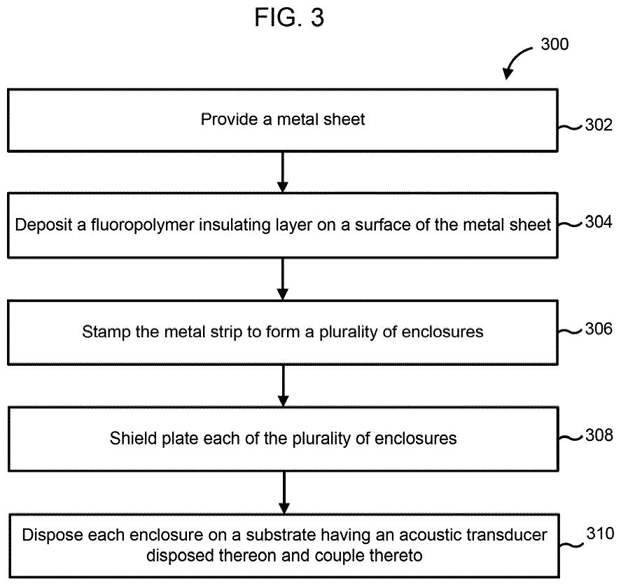

FIG. 3 is a schematic flow diagram of method 300 of forming an enclosure (e.g., the enclosure 130) of a microphone assembly (e.g., the microphone assembly 100) that has a fluoropolymer insulating layer (e.g., the insulating layer 140) disposed on an inner surface thereof. It should be appreciated that while FIG. 3 shows a particular method 300 of forming the enclosure, various enclosures described herein may be formed using any other suitable method.

The method 300 includes providing a metal sheet, at 302. The metal sheet may include the metal sheet 10 (e.g., a metal strip), and may be formed from aluminum, stainless steel, alloys, or any other suitable material. In some embodiments, openings (e.g., the openings 12) may be defined in the metal sheet to define a plurality of sheet portions (e.g., the sheet portions 13), each corresponding to an enclosure to be formed from the metal sheet.

At 304, a fluoropolymer insulating layer (e.g., the insulating layer 140) is deposited on a surface (e.g., one side) of the metal sheet. The fluoropolymer may include any of the fluoropolymers described herein (e.g., polytetrafluoroethylene). The insulating layer has a thickness in range of 30-120 microns (e.g., 30-40 microns).

At 306, the metal sheet is stamped (e.g., using a stamping tool and a mating stamping jig or fixture) to form a plurality of enclosures in the metal sheet such that the insulating layer is disposed on an inner surface of each of the plurality of enclosures. Each enclosure may be separated from the metal sheet during the stamping process, or after the enclosures have been formed.

In some embodiment, each enclosure is shield plates with a shielding material, at 308. For example, an electroplating or electroless plating step is used to plate the enclosure 130 with the shielding material (e.g., copper, nickel, tin, chrome, gold, or any other suitable material). At 310, each enclosure is disposed on a substrate (e.g., the substrate 102) that has an acoustic transducer (e.g., the acoustic transducer 110) disposed thereon and coupled to the substrate, for example, fusion bonded, soldered or bonded via an adhesive to the substrate.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A microphone assembly, comprising:
a substrate;
an acoustic transducer disposed on the substrate, the acoustic transducer configured to generate an electrical signal responsive to acoustic activity;
an integrated circuit disposed on the substrate and electrically coupled to the acoustic transducer, the integrated circuit configured to generate an output signal indicative of the acoustic activity based on the electrical signal from the acoustic transducer;
an enclosure coupled to the substrate and defining an internal volume between the enclosure and the substrate, the enclosure having an outer surface exposed to an outside environment of the microphone assembly, and an inner surface adjacent the internal volume; and
an insulating layer disposed on the inner surface of the enclosure, the insulating layer comprising a fluoropolymer.

2. The microphone assembly of claim 1, wherein the fluoropolymer comprises at least one of polytetrafluoroethylene, fluorinated ethylene propylene, perfluoroalkoxy alkane, poly(ethane-co-tetrafluoroethene), polyvinylfluoride, polyvinylidene fluoride, polychlorotrifluoroethylene, fluorinated ethylene-propylene, polyethylenechlorotrifluoroethylene, chlorotrifluoroethylenevinylidene, tetrafluoroethylene-propylene, perfluoropolyether, or perfluorosulfonic acid.

3. The microphone assembly of claim 2, wherein the fluoropolymer comprises polytetrafluoroethylene.

4. The microphone assembly of claim 1, wherein the enclosure comprises:
a first wall; and
a plurality of second walls projecting axially from the first wall and coupled to the substrate,
wherein the plurality of second walls comprise a portion proximate to the substrate that is not covered by the insulating layer.

5. The microphone assembly of claim 4, wherein a height of the portion is less than three-quarters of a height of the corresponding second wall.

6. The microphone assembly of claim 1, wherein the insulating layer is in continuous contact with the inner surface of the enclosure.

7. The microphone assembly of claim 1, wherein the insulating layer has a thickness in a range of 30-120 microns.

8. An enclosure for a microphone assembly, comprising:
a first wall;
a plurality of second walls projecting axially from the first wall, an end of each of the plurality of second walls configured to be coupled to a substrate to form an internal volume with the substrate within which components of the microphone assembly are disposed, the enclosure having an outer surface configured to exposed to an environment outside the microphone assembly, and an inner surface adjacent the internal volume; and
an insulating layer disposed on the inner surface of the enclosure, the insulating layer comprising a fluoropolymer.

9. The enclosure of claim 8, wherein the fluoropolymer comprises at least one of polytetrafluoroethylene, fluorinated ethylene propylene, perfluoroalkoxy alkane, poly(ethane-co-tetrafluoroethene), polyvinylfluoride, polyvinylidene fluoride, polychlorotrifluoroethylene, fluorinated ethylene-propylene, polyethylenechlorotrifluoroethylene, chlorotrifluoroethylenevinylidene, tetrafluoroethylene-propylene, perfluoropolyether, or perfluorosulfonic acid.

10. The enclosure of claim 9, wherein the fluoropolymer comprises polytetrafluoroethylene.

11. The enclosure of claim 8, wherein each of the plurality of second walls comprise a portion configured to be located proximate to the substrate that is uncovered by the insulating layer.

12. The enclosure of claim 11, wherein a height of the portion is less than three-quarters of a height of the corresponding second wall.

13. The enclosure of claim 8, wherein the insulating layer is in continuous contact with the inner surface of the enclosure.

14. The enclosure of claim 8, wherein the insulating layer has a thickness in a range of 30-120 microns.

15. An enclosure of a microphone assembly, formed by the process of:
providing a metal sheet;
depositing an insulating layer on a surface of the metal sheet, the insulating layer comprising a fluoropolymer;
stamping the metal sheet to form the enclosure in the metal sheet such that the enclosure has an outer surface configured to be exposed to an environment outside the microphone assembly, and an inner surface opposite the outside surface, the insulating layer being disposed on the inner surface; and
separating the enclosure from the metal sheet with the insulating layer disposed thereon.

16. The enclosure of claim 15, wherein the process further comprises shield plating the enclosure with a shielding material.

17. The enclosure of claim 15, wherein the fluoropolymer comprises at least one of polytetrafluoroethylene, fluorinated ethylene propylene, perfluoroalkoxy alkane, poly(ethane-co-tetrafluoroethene), polyvinylfluoride, polyvinylidene fluoride, polychlorotrifluoroethylene, fluorinated ethylene-propylene, polyethylenechlorotrifluoroethylene, chlorotrifluoroethylenevinylidene, tetrafluoroethylene-propylene, perfluoropolyether, or perfluorosulfonic acid.

18. The enclosure of claim 17, wherein the fluoropolymer comprises polytetrafluoroethylene.

19. The enclosure of claim 15, wherein the enclosure comprises:
a first wall; and
a plurality of second walls projecting axially from the first wall, an end of each of the plurality of second walls configured to be coupled to a substrate of the microphone assembly to form an internal volume with the substrate within which components of the microphone assembly are disposed,
wherein the plurality of second walls comprise a portion proximate to the substrate that is uncovered by the insulating layer.

20. The enclosure of claim 15, wherein the insulating layer has a thickness in a range of 30-120 microns.
